(19) United States
(12) Patent Application Publication
(10) Pub. No.: US 2003/0151108 A1
(43) Pub. Date: Aug. 14, 2003

(54) Image sensor and method for packaging the same

(76) Inventor: Chung Hsien Hsin, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 10/075,716

(22) Filed: Feb. 13, 2002

(51) Int. Cl. H01L 31/0203

(52) U.S. Cl. 257/433

(57) ABSTRACT

An image sensor of this invention includes a substrate, a photosensitive chip, an encapsulant, and a transparent layer. The photosensitive chip is arranged on the substrate and is electrically connected to the substrate via a plurality of wires. The encapsulant is adhered or coated onto the substrate and at the periphery of the photosensitive chip to surround the photosensitive chip. The height of the encapsulant is slightly greater than the thickness of the photosensitive chip. The transparent layer is placed on the encapsulant to cover the photosensitive chip. A method for packaging the image sensor is also disclosed. According to the structure and method, the manufacturing processes can be simplified, the yield can be increased, and the manufacturing costs can be lowered.

### BACKGROUND OF THE INVENTION

1. Field of the Invention

This invention relates to an image sensor and a method for packaging the same, and in particular, to an image sensor capable of simplifying the manufacturing processes, improving the yields, and lowering the manufacturing costs.

2. Description of the Related Art

A general sensor is used for sensing signals, which may be optical or audio signals. The sensor of the invention is used for receiving image signals or optical signals. After receiving image signals, the image sensor converts the image signals into electrical signals which are then transmitted to a printed circuit board via a substrate.

Referring to FIG. 1, a conventional method for packaging an image sensor includes the steps of:

providing a substrate 10 having an upper surface formed with first contact points 18 and a lower surface formed with second contact points 24;

providing a spacer 12 on the substrate 10 to form a cavity 11;

providing a photosensitive chip 14 on the substrate 10 and within the cavity 11, a plurality of bonding pads 20 being formed on the photosensitive chip 14;

providing a plurality of wires 16 for electrically connecting the bonding pads 20 of the photosensitive chip 14 to the first contact points 18 of the substrate 10; and

providing a transparent layer 22, which is coated with an adhesive layer 23, on the spacer 12, for covering the photosensitive chip 14.

The package processes for the image sensor is then completed.

The image sensor has the following drawbacks.

1. The processes are complicated because the spacer has to be arranged on the substrate 10, and the transparent layer 22 has to be coated with the adhesive layer 23 and then adhered on the spacer 12.

2. After the transparent layer 22 is placed on the spacer 12 to cover the photosensitive chip, the plurality of wires 16 are not well protected. Thus, external impurities may tend to damage the plurality of wires 16, thereby influencing the signal transmission effects for the photosensitive chip 14 and lowering the overall yield.

In view of the above-mentioned drawbacks, it is therefore an object of the invention to provide a package structure and method for an image sensor capable of effectively solving the problems stated above, facilitating the manufacturing processes, and lowering the manufacturing costs.

### SUMMARY OF THE INVENTION

An object of the invention is to provide a package structure and method for an image sensor capable of effectively solving the problems stated above, facilitating the manufacturing processes, and lowering the manufacturing costs.

Another object of the invention is to provide a package structure and method for an image sensor capable of protecting the wires from being damaged, improving the signal transmission effects, and increasing the yields.

According to one aspect of the invention, an image sensor of this invention includes a substrate, a photosensitive chip, an encapsulant, and a transparent layer. The photosensitive chip is arranged on the substrate and is electrically connected to the substrate via a plurality of wires. The encapsulant is adhered or coated onto the substrate and at the periphery of the photosensitive chip to surround the photosensitive chip. The height of the encapsulant is slightly greater than the thickness of the photosensitive chip. The transparent layer is placed on the encapsulant to cover the photosensitive chip.

According to the structure of the image sensor, the manufacturing processes can be simplified, the yield can be increased, and the manufacturing costs can be lowered.

### BRIEF DESCRIPTION OF THE DRAWINGS

FIG. 1 is a schematically cross-sectional view showing a conventional image sensor.

FIG. 2 is a schematically cross-sectional view showing an image sensor of the invention.

FIG. 3 is a first schematic illustration showing a method for packaging the image sensor of the invention.

FIG. 4 is a second schematic illustration showing the method for packaging the image sensor of the invention.

FIG. 5 is a third schematic illustration showing the method for packaging the image sensor of the invention.

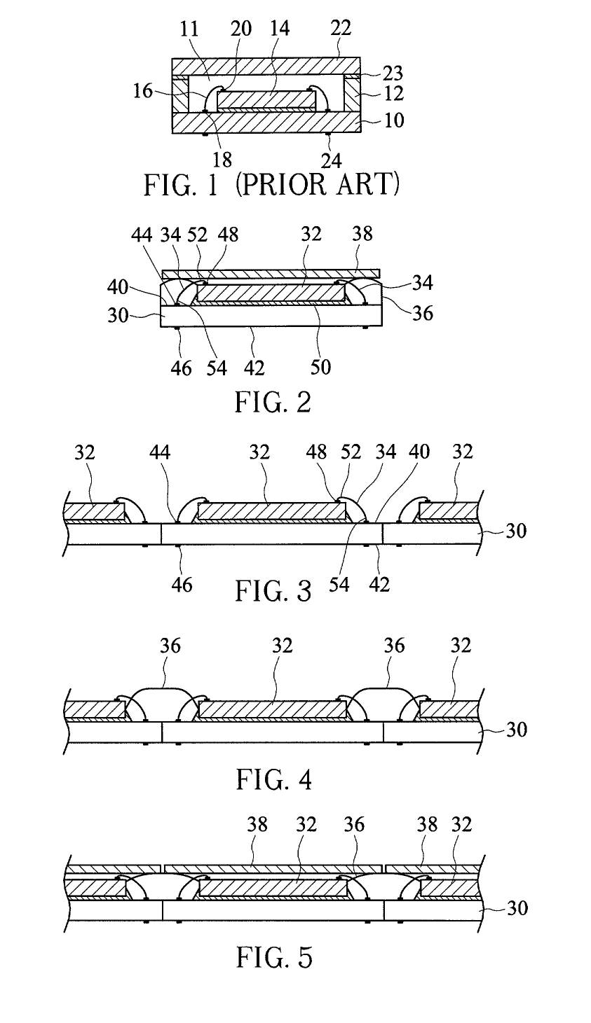

### DETAIL DESCRIPTION OF THE INVENTION

Referring to FIG. 2, the image sensor of the invention includes a substrate 30, a photosensitive chip 32, a plurality of wires 34, an encapsulant 36 and a transparent layer 38.

The substrate 30 has an upper surface 40 and a lower surface 42. The upper surface 40 is formed with a plurality of first connection points 44. On the other hand, the lower surface 42 is formed with a plurality of second connection points 46 for electrically connecting to a printed circuit board (not shown).

The photosensitive chip 32 is adhered onto the upper surface 40 of the substrate 30 through an adhesive layer 50. A plurality of bonding pads 48 are formed on the photosensitive chip 32.

Each of the plurality of wires 34 has a first terminal 52 and a second terminal 54. The first terminals 52 are electrically connected to the bonding pads 48 of the photosensitive chip 32, respectively. On the other hand, the second terminals 54 are electrically connected to the first connection points 44 of the substrate 30, respectively. Accordingly, signals from the photosensitive chip 32 can be transmitted to the substrate 30.

The encapsulant 36 is adhered onto the upper surface 40 of the substrate 10 and positioned at the periphery of the photosensitive chip 32 to surround the photosensitive chip 32 and to cover and protect the plurality of wires 34. The height of the encapsulant 36 is slightly greater than the thickness of the photosensitive chip 32.

The transparent layer 38 is adhered onto the encapsulant 36 by way of the adhesive property of the encapsulant 36, so as to cover the photosensitive chip 32.

Since the encapsulant 36 surrounds the photosensitive chip 32 and the transparent layer 38 is directly placed on the encapsulant 36, the manufacturing processes can be simplified and the manufacturing costs can be lowered. Furthermore, since the encapsulant can protect the plurality of wires 34 from being damaged, the signal transmission effects can be improved to achieve the functions and objects of the invention.

Referring to FIG. 3, which is a first schematic illustration showing a method for packaging the image sensor of the invention, the method of the invention includes the steps of:

providing a substrate 30 having an upper surface 40 and a lower surface 42, the upper surface 40 is formed with a plurality of first connection points 44, and the lower surface 42 is formed with a plurality of second connection points 46 for electrically connecting to a printed circuit board (not shown);

providing a plurality of photosensitive chips 32 placed on the substrate 30;

electrically connecting the first terminals 52 of the plurality of wires 34 to the bonding pads 48 of the photosensitive chips 32, respectively; and

electrically connecting the second terminals 54 to the first connection points 44 of the substrate 30.

Referring to FIGS. 4 and 5, the method of the invention further includes the steps of:

providing the encapsulant 36 coated and adhered onto the upper surface 40 of the substrate 30 and positioned at a periphery of each of the photosensitive chips for surrounding each of the photosensitive chips 32 and covering the plurality of wires 34, the height of the encapsulant 36 being greater than the thickness of each photosensitive chip 32;

providing a plurality of transparent layers 38 placed on the encapsulant 36 and corresponding to the photosensitive chips 32 to cover the photosensitive chips 32, respectively, the transparent layer 38 being adhered onto the encapsulant 36 by way of the adhesive property of the encapsulant 36; and

cutting the package of the image sensors into a plurality of package bodies of a single image sensor, as shown in FIG. 2.

According to the structure and method of the image sensor of the invention, there are some advantages as follows.

1. Since the encapsulant 36 serves as the spacer and the transparent layer 38 is directly adhered onto the encapsulant 36 to cover the photosensitive chip 32, the manufacturing processes is simple and the manufacturing costs can be lowered.

2. Since the plurality of wires 34 are covered or sealed by the encapsulant 36, the wires 34 are free from the contamination of external impurities, the signal transmission effects can be improved, and the yield can be increased.

3. Since the transparent layer 38 is adhered onto the encapsulant 36 by way of the adhesive property of the encapsulant 36 itself, the process of encapsulant coating can be simplified, and the manufacturing costs can be lowered.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor for receiving optical signals and converting the optical signals into electrical signals that are to be transmitted to a printed circuit board, the image sensor comprising:
a substrate including an upper surface and a lower surface, the upper surface being formed with a plurality of first connection points, and the lower surface being formed with a plurality of second connection points for electrically connecting to the printed circuit board;
a photosensitive chip arranged on the upper surface of the substrate, a plurality of bonding pads being formed on the photosensitive chip;
a plurality of wires each including a first terminal and a second terminal, the first terminals being electrically connected to the bonding pads of the photosensitive chip, respectively, and the second terminals being electrically connected to first connection points of the substrate, respectively;
an encapsulant adhered onto the upper surface of the substrate and positioned at a periphery of the photosensitive chip for surrounding the photosensitive chip, the height of the encapsulant being greater than the thickness of the photosensitive chip; and
a transparent layer placed on the encapsulant to cover the photosensitive chip.

2. The image sensor according to claim 1, wherein the encapsulant covers the plurality of wires.

3. The image sensor according to claim 1, wherein the transparent layer is directly adhered onto the encapsulant.

4. A method for packaging an image sensor, comprising the steps of:
providing a substrate having an upper surface and a lower surface, the upper surface being formed with a plurality of first connection points, and the lower surface being formed with a plurality of second connection points;
providing a photosensitive chip arranged on the upper surface of the substrate, a plurality of bonding pads being formed on the photosensitive chip;
providing a plurality of wires each including a first terminal and a second terminal, the first terminals being electrically connected to the bonding pads of the photosensitive chip, respectively, and the second terminals being electrically connected to the first connection points of the substrate, respectively;
providing an encapsulant adhered onto the upper surface of the substrate and positioned at a periphery of the photosensitive chip for surrounding the photosensitive chip, the height of the encapsulant being greater than the thickness of the photosensitive chip; and
providing a transparent layer placed on the encapsulant to cover the photosensitive chip.

5. The method according to claim 4, wherein the encapsulant covers the plurality of wires.

6. The method according to claim 4, wherein the transparent layer is directly adhered onto the encapsulant.

7. A method for packaging an image sensor, comprising the steps of:
providing a substrate having an upper surface and a lower surface, the upper surface being formed with a plurality of first connection points, and the lower surface being formed with a plurality of second connection points;
providing a plurality of photosensitive chips arranged on the upper surface of the substrate, a plurality of bonding pads being formed on each of the photosensitive chips;
providing a plurality of wires each including a first terminal and a second terminal, the first terminals being electrically connected to the bonding pads of the photosensitive chips, respectively, and the second terminals being electrically connected to the first connection points of the substrate, respectively;
providing an encapsulant adhered onto the upper surface of the substrate and positioned at a periphery of each of the photosensitive chips for surrounding each of the photosensitive chips, the height of the encapsulant being greater than the thickness of the photosensitive chips; and
providing a plurality of transparent layers placed on the encapsulant to cover the photosensitive chips, so as to complete the package of the image sensors; and
cutting the package of the image sensors into a plurality of package bodies of a single image sensor.

8. The method according to claim 7, wherein the encapsulant covers the plurality of wires.

9. The method according to claim 7, wherein the transparent layer is directly adhered onto the encapsulant.
